(19) United States
(12) Patent Application Publication
(10) Pub. No.: US 2024/0318311 A1
(43) Pub. Date: Sep. 26, 2024

(54) METHOD FOR REDUCING INCUBATION PERIOD OF SILICON NITRIDE LAYER DEPOSITION, STRUCTURE FORMED USING THE METHOD, AND SYSTEM FOR PERFORMING THE METHOD

(71) Applicant: ASM IP Holding B.V., Almere (NL)

(72) Inventors: Agung Setiadi, Tokyo (JP); Hiroki Matsuda, Tokyo (JP); Jun Kawahara, Tokyo (JP)

(21) Appl. No.: 18/610,654

(22) Filed: Mar. 20, 2024

Related U.S. Application Data
(60) Provisional application No. 63/454,170, filed on Mar. 23, 2023.

(51) Int. Cl. C23C 16/455; C23C 16/34; C23C 16/515; H01J 37/32; H01L 21/02

(52) U.S. Cl. CPC C23C 16/45542; C23C 16/345; C23C 16/45534; C23C 16/515; H01J 37/32146; H01J 37/3244; H01J 37/32816; H01L 21/0217; H01L 21/02211; H01L 21/02274; H01L 21/0228; H01L 21/02315; H01J 2237/332

(57) ABSTRACT

Methods and systems for pretreating a surface prior to depositing silicon nitride on the surface are disclosed. Exemplary methods include pretreating the surface by exposing the surface to activated species formed from one or more gases comprising nitrogen and hydrogen under conditions that reduce incubation time for depositing the silicon nitride.

### CROSS-REFERENCE TO RELATED APPLICATIONS

This application claims priority to U.S. Provisional Patent Application Ser. No. 63/454,170 filed Mar. 23, 2023 and titled METHOD FOR REDUCING INCUBATION PERIOD OF SILICON NITRIDE LAYER DEPOSITION, STRUCTURE FORMED USING THE METHOD, AND SYSTEM FOR PERFORMING THE METHOD, the disclosure of which is hereby incorporated by reference in its entirety.

### FIELD OF INVENTION

The present disclosure generally relates to methods of forming thin films and to structures including the thin films. More particularly, the disclosure relates to methods of depositing silicon nitride layers, to structures including such layers, and to systems for depositing the layers.

### BACKGROUND OF THE DISCLOSURE

Silicon nitride films are used for a wide variety of applications. For example, such films can be used as insulating regions, as etch stop regions, as spacers, to protect trench structures, for etch-resistant protective regions, or the like, in the formation of electronic devices.

In some applications, it may be desirable to deposit relatively thin—e.g., less than 10 nm or less than 5 nm thick—and uniform films of silicon nitride on a surface of a substrate. Further, it is often desirable to deposit films of uniform thickness over a three-dimensional surface on a surface of a substrate.

Plasma-enhanced deposition is used in several applications to deposit silicon nitride films to, for example, reduce a deposition temperature and/or increase a deposition rate. Growth incubation of plasma-enhanced deposited silicon nitride films can be highly dependent on a material on a surface of a substrate. By way of example, in the case of depositing silicon nitride over a silicon oxide trench structure using a plasma-enhanced process, up to 4 nm of incubation growth can be observed. This implies that, for a desired 4 nm film growth, a target number of cycles equivalent to 8 nm film may be used to deposit the 4 nm thick film. As a result, productivity is about 50% of desired productivity. Once an initial layer of silicon nitride is deposited onto the surface silicon nitride film, growth can be relatively uniform.

One approach to reduce an incubation time for plasma-enhanced silicon nitride film deposition includes increasing a time that a precursor is fed to a reaction chamber and increasing a time that radio frequency (RF) power is applied during initial deposition cycles of a plasma-enhanced silicon nitride deposition process. However, because a precursor is used during the incubation process, such an approach can result in film growth during the incubation process.

Accordingly, improved methods and systems for forming structures including silicon nitride films are desired.

Any discussion of problems and solutions set forth in this section has been included in this disclosure solely for the purpose of providing a context for the present disclosure and should not be taken as an admission that any or all of the discussion was known at the time the invention was made.

### SUMMARY OF THE DISCLOSURE

Various embodiments of the present disclosure relate to methods of forming silicon nitride on a surface of a substrate, to systems for performing the methods, and to the structures including silicon nitride films. While the ways in which various embodiments of the present disclosure address drawbacks of prior methods and systems are discussed in more detail below, in general, various embodiments of the disclosure provide improved methods of depositing silicon nitride using a pretreatment process. The pretreatment process can be performed at a relatively high pressure (e.g., greater than or equal to 3000 Pa) to reduce incubation time, while mitigating ion bombardment to a surface of the substrate, and/or while removing residue from the surface.

Exemplary methods described below provide relatively efficient methods of pretreating a surface of a substrate to allow for relatively uniform deposition incubation times-even across different materials on a surface of a substrate and/or across different substrates. Further, exemplary methods can provide relatively uniform deposition incubation across a feature, such as along a height of a trench or protrusion on a substrate surface. Yet further, exemplary methods can remove fluorine residue on a surface of a substrate—e.g., without an additional pre-process residue removal step.

In accordance with at least one embodiment of the disclosure, a method of forming silicon nitride on a surface of a substrate includes providing a substrate within a reaction chamber, performing a pretreatment step on a surface of the substrate and within the reaction chamber, and depositing the silicon nitride on the treated surface. In accordance with examples of the disclosure, the pretreatment step includes providing one or more gases comprising nitrogen and hydrogen to the reaction chamber, forming activated species from the one or more gases comprising nitrogen and hydrogen, and using the activated species to form a treated surface. In accordance with further examples, a pressure within the reaction chamber during the step of performing the pretreatment step is greater than or equal to 3000 Pa—e.g., between 3000 and about 4000 Pa. The one or more gases comprising nitrogen and hydrogen can include, for example, one or more of nitrogen (N₂), hydrogen (H₂), ammonia, hydrazine, and/or a hydrazine derivative (e.g., hydrazine with one or more H replaced with an independently selected C1-C4 alkyl group), any which may be combined with a second gas, such as one or more of argon, helium, and nitrogen. The step of forming activated species from the one or more gases comprising nitrogen and hydrogen and using the activated species to form a treated surface can include a pulsed plasma process—e.g., wherein a power for plasma formation is pulsed. In accordance with examples of these embodiments, the step of depositing a layer of silicon nitride includes a plasma-enhanced (e.g., cyclical) deposition process. The cyclical process can include at least one of a reactant and a precursor exposed to a plasma to form activated species. In accordance with further examples, one or more reactants is continuously flowed into the reaction chamber during the steps of performing a pretreatment step and depositing the silicon nitride on the treated surface. In accordance with further examples, a pressure within the reaction chamber during the step of performing a pretreatment is greater than a pressure within the reaction chamber during the step of depositing the silicon nitride.

In accordance with additional embodiments of the disclosure, a system for performing a method as described herein and/or for forming a structure as described herein is disclosed.

For purposes of summarizing the invention and the advantages achieved over the prior art, certain objects and advantages of the invention may have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein, without necessarily achieving other objects or advantages as may be taught or suggested herein. These and other embodiments will become readily apparent to those skilled in the art from the following detailed description of certain embodiments having reference to the figures, the invention not being limited to any particular embodiment disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a timing sequence of a method of forming silicon nitride on a surface of a substrate in accordance with at least one embodiment of the disclosure.

FIG. 2 illustrates incubation improvement using a method in accordance with an example of the disclosure.

FIG. 3 illustrates film thickness differences of silicon nitride films deposited with and without a pretreatment step in accordance with examples of the disclosure.

FIG. 4 illustrates a system configured for executing a method as described herein.

FIG. 5 illustrates a system in accordance with yet additional examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed not be limited by the particular disclosed embodiments described below.

As set forth in more detail below, examples of the disclosure provide improved methods and systems for forming silicon nitride on a surface of a substrate. Exemplary methods include use of a pretreatment step to reduce an incubation associated with forming silicon nitride on a surface of a substrate. The pretreatment step can provide for more uniform deposition of silicon nitride over different materials and/or materials formed using different techniques and/or having different thicknesses. Additionally or alternatively, examples of the disclosure can provide improved step coverage of silicon nitride films deposited over features on a surface of a substrate.

As used herein, the term “substrate” can refer to any underlying material or materials that may be used to form, or upon which, a device, a circuit, or a film may be formed. A substrate can include a bulk material, such as silicon (e.g., single-crystal silicon), and can include one or more layers overlying the bulk material. Further, the substrate can include various features, such as trenches, recesses, protrusions, lines, or the like formed within or on at least a portion of the substrate. In accordance with examples of the disclosure, the substrate includes at least two different materials and/or materials that include different surface terminations, prior to pretreatment.

As used herein, the term “cyclical deposition” can refer to a sequential introduction of precursors and/or reactants into a reaction chamber to deposit a layer over a substrate and can include processing techniques, such as atomic layer deposition and cyclical chemical vapor deposition. In some cases, one or more reactants can be continuously provided to a reaction chamber and one or more of a precursor and a deposition plasma power can be pulsed. A reaction chamber can be purged after the introduction of one or more of the precursors and/or reactants.

As used herein, the term “atomic layer deposition” (ALD) can refer to a vapor deposition process in which deposition cycles, typically a plurality of consecutive deposition cycles, are conducted in a process chamber. Generally, during each cycle, a precursor is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the reaction chamber (or may be continuously provided to the reaction chamber) for use in converting the chemisorbed precursor to the desired material on the substrate surface. The reactant can be capable of further reaction with the precursor. Further, purging steps can also be utilized during each cycle to remove excess precursor from the process chamber and/or remove excess reactant and/or reaction byproducts from the process chamber after conversion of the chemisorbed precursor. The purging can be effected using an inert gas, non-plasma-activated reactant(s), a vacuum, or any combination thereof. When one or more gases are activated using a plasma during an ALD process, the process is referred to as a plasma-enhanced ALD (PEALD) process.

As used herein, the term “cyclical chemical vapor deposition” can refer to any process in which a substrate is sequentially exposed to pulses of a reactant, a precursor, plasma power, or any combination thereof.

A layer including silicon nitride (SiN) or simply silicon nitride can comprise, consist essentially of, or consist of silicon nitride material. Films consisting of silicon nitride can include an acceptable amount of impurities, such as carbon, chlorine or other halogen, and/or hydrogen, that may originate from one or more precursors used to deposit the silicon nitride layers. As used herein, SiN or silicon nitride refers to a compound that includes silicon and nitrogen. SiN can be represented as SiNₓ, where x varies from, for example, about 0.5 to about 2.0, where some Si—N bonds are formed. In some cases, x may vary from about 0.9 to about 1.7, from about 1.0 to about 1.5, or from about 1.2 to about 1.4. In some embodiments, silicon nitride is formed where Si has an oxidation state of +IV and the amount of nitride in the material may vary.

In this disclosure, “continuously” can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like, in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

In accordance with examples of the disclosure, a method of forming silicon nitride on a surface of a substrate is provided. The method can include providing a substrate within a reaction chamber, performing a pretreatment step on a surface of the substrate and within the reaction chamber, and depositing the silicon nitride on the treated surface. As set forth in more detail below, the pretreatment step can include providing one or more gases comprising nitrogen and hydrogen to the reaction chamber, forming activated species from the one or more gases comprising nitrogen and hydrogen, and using the activated species to form a treated surface. In accordance with further examples, to mitigate ion bombardment and possible damage to a surface of a substrate, a pressure within the reaction chamber during the step of performing the pretreatment step is greater than or equal to 3000 Pa.

During the step of providing a substrate within a reaction chamber, a substrate is provided into a reaction chamber of a reactor suitable for plasma-enhanced processing. In accordance with examples of the disclosure, the reaction chamber can form part of a cyclical deposition or an atomic layer deposition (ALD) reactor. Various steps of methods described herein can be performed within a single reaction chamber or can be performed in multiple reaction chambers, such as reaction chambers of a cluster tool—e.g., without exposing the surface of the substrate to an ambient atmosphere. A reactor including the reaction chamber can be provided with a heater to activate the reactions by elevating the temperature of one or more of the substrate and/or the reactants/precursors. By way of examples, the steps of performing a pretreatment step on a surface of the substrate and depositing the silicon nitride on the treated surface are performed within a single reaction chamber without an air or vacuum break.

The substrate can be brought to a desired temperature and pressure for step 104 and/or step 106. By way of examples, a temperature (e.g., of a substrate or a substrate support) within a reaction chamber can be between about 100° C. and about 600° C. or about 300° C. and about 550° C. A pressure within the reaction chamber can be about 100 Pa to about 6600 Pa.

The substrate provided can include a surface that includes one or more materials-sometimes referred to herein as material surfaces. Exemplary materials include semiconductor (e.g., Group IV) material; metal; oxides, such as silicon oxides; metal oxides; metal nitrides; semiconductor (e.g., Group IV) nitrides, such as silicon nitrides and silicon oxynitrides, other dielectric materials, and any combination of such materials, any of which can be thermally deposited or deposited with the assistance of a plasma. By way of examples, the substrate can include one or two or more of silicon, silicon oxide, a metal, or a metal oxide, with or without fluorine terminal bonds.

During the pretreatment step, the substrate is exposed to activated species formed from one or more gases comprising nitrogen and hydrogen. During this step, N—H and/or N—H₂ groups can form on a surface of the substrate. The formation of such groups on the surface of the substrate facilitates subsequent (e.g., CVD or cyclic) deposition of silicon nitride on the surface of the substrate, even when the surface comprises different materials.

By way of examples, substrate surfaces can include native oxide and/or thick silicon oxide film. Without pretreatment as described herein, an incubation period for plasma-enhanced deposition of silicon nitride can be highly dependent on a quality of an underlying layer. For example, deposition of silicon nitride over a native silicon oxide can be achieved with relatively low incubation, while incubation of silicon nitride over a thick, high quality silicon oxide film can exhibit a much higher incubation. However, use of the pretreatment step can reduce or eliminate the incubation period over both surfaces, thereby allowing for more uniform deposition of silicon nitride over the surfaces-whether on the same or on different substrates. In accordance with examples of the disclosure, when one or more substrates have multiple material surfaces to be pretreated, a pretreatment time is selected to be greater than a minimum pretreatment of a surface with the longer pretreatment time, such that the surface termination across the material surfaces is substantially similar. Another advantage of methods described herein is that a uniformity of a silicon nitride film deposited over a feature on or within a substrate can be improved. By way of examples, the silicon nitride may be deposited over the one or more features, i.e., high aspect ratio features (e.g., having an aspect ratio greater than or equal to 10 or 12), with a step coverage greater than approximately 90%, or greater than approximately 95%, or greater than approximately 99%, or even substantially equal to 100%. As used herein, the term “step coverage” is defined as percentage ratio of a thickness of the metal oxide film on a sidewall of a feature (e.g., trench or protrusion) to the thickness of the metal oxide on a horizontal surface of the substrate. In these cases, a time period of the pretreatment processes can be selected to obtain the desired step coverage. In accordance with further examples, the pretreatment results in substantially uniform surface bonding states of the treated surface.

As noted above, the pretreatment step can include providing one or more gases comprising nitrogen and hydrogen to the reaction chamber, forming activated species from the one or more gases comprising nitrogen and hydrogen, and using the activated species to form a treated surface. The pretreatment step can be used to, for example, improve efficiency of or reduce an overall time of the method. For example, a total process time to deposit a silicon nitride film, including pretreatment, may be reduced by using the pretreatment step.

In accordance with examples, of the disclosure, the one or more gases comprising nitrogen and hydrogen comprise one or more of ammonia, hydrazine, and a hydrazine derivative. The hydrazine derivative can include one or more independently-selected C1-C4 substituted groups. The one or more gases comprising nitrogen and hydrogen can include a second gas comprising one or more of argon, helium, and nitrogen. By way of illustration, the one or more gases including nitrogen and hydrogen can include nitrogen and hydrogen, nitrogen and ammonia, nitrogen, hydrogen, and ammonia, or any of these with one or more of helium and argon.

The second gas can constitute about 0 to about 60 or about 1 to about 30 vol % of a gas mixture including the one or more gases comprising nitrogen and hydrogen. In some cases, the one or more gases comprising nitrogen and hydrogen comprise a mixture of nitrogen and hydrogen, and may include a second gas, such as argon and/or helium. The gas mixture including nitrogen and hydrogen can include from about 70 to about 100 volumetric percent nitrogen and/or from about 0 to about 1 volumetric percent hydrogen. As set forth in more detail below, the one or more gases comprising nitrogen and hydrogen can be provided continuously during performing the pretreatment step and the step of depositing the silicon nitride.

A power used to form a plasma during the step of forming activated species from the one or more gases comprising nitrogen and hydrogen can be between about 10 W and about 2 kW or between about 100 W and about 900 W. A duration of the performing a pretreatment step (e.g., a duration of applied plasma power during this step) can be between about 1 and about 300 seconds or between about 30 and about 240 seconds.

A pressure within the reaction chamber during the pretreatment step is relatively high. In accordance with examples of the disclosure, a pressure within the reaction chamber during the step of performing a pretreatment is greater than a pressure within the reaction chamber during the step of depositing the silicon nitride. In some cases, a pressure within the reaction chamber during the step of performing a pretreatment is more than 150% of a pressure within the reaction chamber during the step of depositing the silicon nitride. By way of examples, a pressure within the reaction chamber during performing a pretreatment step is between greater than 3000 Pa and 4000 Pa.

A temperature of a substrate during the pretreatment step can be between about 100° C. and about 600° C. or about 300° C. and about 550° C.

Once the pretreatment step is completed, silicon nitride is deposited on the treated surface. The step of depositing the silicon nitride can be a can include CVD or a cyclical deposition process. The cyclical process can include pulsing a silicon precursor to the reaction chamber for a silicon precursor pulse period, providing the one or more gases comprising nitrogen and hydrogen, and pulsing a plasma power for a plasma power pulse period. The deposition cycles can be repeated one or more times—e.g., from about 10 to about 1000 cycles and/or to form silicon nitride having a thickness between about 1 and about 100 nm or between about 1 and about 10 nm.

In accordance with various examples of the disclosure, the silicon precursor is thermally adsorbed or thermally reacts with the treated surface. In other words, the silicon precursor is not exposed to a plasma process.

Silicon precursors suitable for use with methods described herein include silicon and hydrogen, and may include nitrogen and/or a halogen. For example, a silicon precursor can be selected from the group consisting of a silane, a silylamine, an aminosilane, a halogenated silicon compound, or the like. By way of examples, the silicon precursor can be selected from one or more of silicon precursors that preferentially react with OH terminal groups on a surface of a substrate. Such silicon precursors include silanes, silylamines, and aminosilanes. Particular examples include silane (SiH₄), disilane (Si₂H₆), trisilane (Si₃H₈), tetrasilane (Si₄H₁₀), N(Si₂H₅)₃, trisilylamine N(SiH₃)₃, N(SiMe₃)(SiHMeNMe₂)2, 2,2-disilyltrisilane (Si(SiH₃)₄), trisdimethylaminosilane (SiH(NMe₂)₃), bis(diethylamino)silane (SiH₂(NEt₂)₂) (BEDAS), bis(tert-butylamino)silane (SiH₂(NHtBu)₂) (BTBAS), di-isopropylamido)silane (SiH₃(NiPr₂)) (DIPAS), where Me represents a methyl group, Et represents an ethyl group, tBu represents a tert-butyl group, and iPr represents an isopropyl group. Alternatively, some precursors may preferentially react with activated cites comprising —NH terminal bonds. Exemplary precursors that react with such activated cites include halogenated silicon compounds, such as silicon compounds comprising one or more of Cl and I. Particular examples include trichloro disilane (Si₂Cl₃H₃), pentachloro disilane (Si₂Cl₅H), hexachloro disilane (Si₂Cl₆), octachlorotrisilane (Si₃Cl₈), dichloro silane (SiCl₂H₂), dimethyldichlorosilane (SiCl₂Me₂), tetrachloro silane (SiCl₄), tetraiodo silane (SiI₄), triiodo silane (SiI₃H), and diiodo silane (SiI₂H₂).

A flowrate of the silicon precursor into the reaction chamber can range from, for example, about 10 sccm to about 5 slm. A carrier gas, such as nitrogen, can be co-flowed with the silicon precursor. A flowrate of the carrier into the reaction chamber can range from, for example, about 0 slm to about 50 slm. A temperature of a substrate can be between about 50° C. and about 700° C. or between about 100° C. and about 600° C. or between about 300° C. and about 550° C. A silicon precursor can be flowed to the reaction chamber for a period of about 0.05 sec to about 10 min. Then, the flow of silicon precursor can cease and the reaction chamber can be purged.

During the step of providing the one or more gases comprising nitrogen and hydrogen during deposition, the one or more gases comprising nitrogen and hydrogen as described above can be provided to the reaction chamber. The activated species can be formed by applying a deposition plasma power of between about 10 and about 2000 or about 100 and about 900 W. A duration for the application of the plasma power during this step can be between about 0.05 and about 60 or between about 0.5 and about 30 seconds. The plasma power during the deposition step can be the same or different than the plasma power used during the pretreatment step. In accordance with examples of the disclosure, the plasma power during deposition is greater or less than the power used during the pretreatment step.

As noted above, a pressure within the reaction chamber during the step of depositing the silicon nitride on the treated surface can be less than the pressure within the reaction chamber during the step of performing a pretreatment step. By way of example, the pressure within the reaction chamber during the step of depositing the silicon nitride on the treated surface can be between 350 Pa and 3000 Pa or less than 3000 Pa.

In some cases, it may be desirable to pulse pretreatment plasma power and/or deposition plasma power to, for example, reduce any damage to a substrate surface that may occur during a pretreatment process, while still achieving lower incubation and relatively high throughput. An on power on duration can range from about 10% to about 90%. An off power on duration can range from about 10% to about 90%. A pulse frequency can range from about 1000 Hz to about 100000 Hz. An on-time duty ratio can be greater than 50%. A frequency of power used to form a plasma during the step of exposing the substrate to activated species 106 can be between about 100 kHz and about 2.45 GHz.

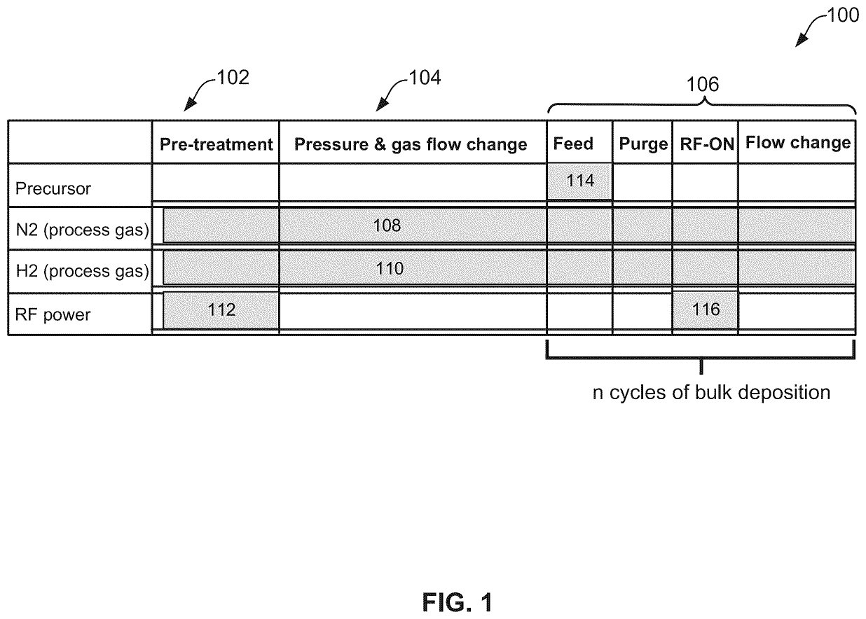

FIG. 1 illustrates a timing sequence 100 of a method of forming silicon nitride on a surface of a substrate in accordance with at least one embodiment of the disclosure. Timing sequence 100 includes a pretreatment step 102, a pressure and gas flow adjustment period 104, and a silicon nitride deposition step 106. In the illustrated example, pretreatment step 102 includes continuously providing one or more gases comprising nitrogen and hydrogen to the reaction chamber (108, 110) and providing a pretreatment plasma power for a duration 112. The conditions for pretreatment step 102 can be as described above.

As illustrated, continuously providing one or more gases comprising nitrogen and hydrogen to the reaction chamber (108, 110) can continue through step 104 and step 106. A duration of step 104 can be between about 5 and about 60 seconds. During step 104, the flowrates of the one or more gases comprising nitrogen and hydrogen can be altered—e.g., increased or decreased and allowed to stabilize for step 106. Additionally or alternatively a mix ratio of the one or more gases comprising nitrogen and hydrogen and/or a dilution of the one or more gases comprising nitrogen and hydrogen can be changed during step 106.

During deposition step 106, a silicon precursor is pulsed to the reaction chamber for a period 114 and a plasma is applied to form activated species during period 116. As illustrated, the silicon precursor pulse period 1114 ceases prior to the step of pulsing a plasma power for the plasma power pulse period 116. As further illustrated, continuously providing one or more gases comprising nitrogen and hydrogen to the reaction chamber (108, 110) can continue during step 106 and provide a purge between periods 114 and 116.

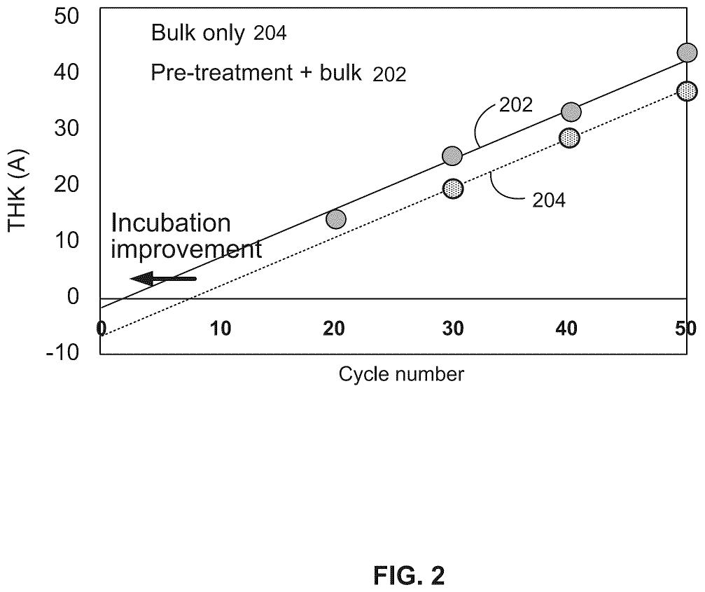

FIG. 2 illustrates incubation improvement using a method in accordance with an example of the disclosure. In particular, FIG. 2 illustrates that a number of cycles to reach a desired film thickness can be reduced (e.g., from about 8 to about 2 cycles) using a pretreatment step as described herein.

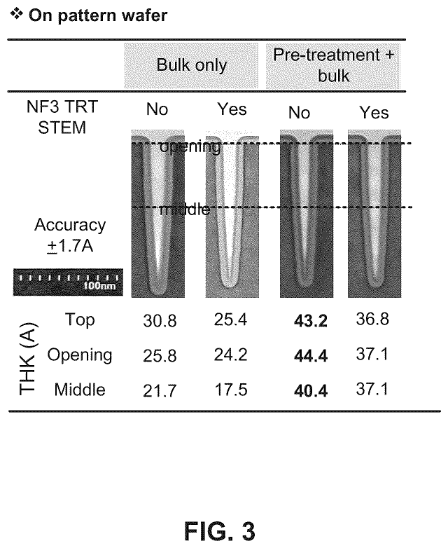

FIG. 3 illustrates film thickness differences of silicon nitride films deposited with and without a pretreatment step in accordance with examples of the disclosure. In some cases, a substrate surface was treated with a fluorine-based (NF₃) plasma to increase an incubation time. The results illustrated in FIG. 3 show that the pretreatment step reduces incubation time and also removes residual fluorine from a surface of the substrate. Both uniformity and thickness were improved using the pretreatment step.

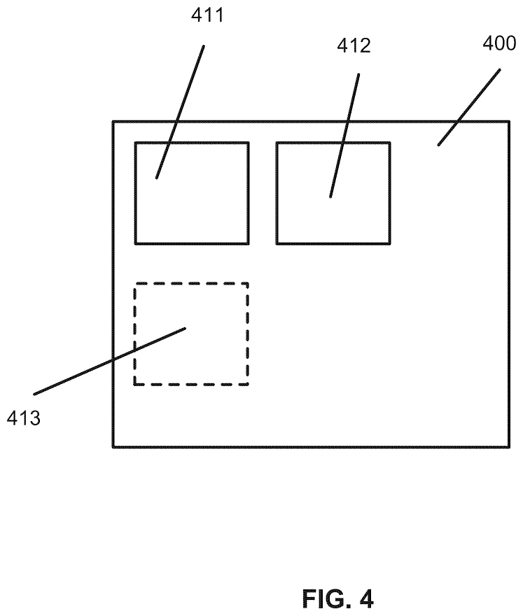

Further described, now referring to FIG. 4, is a system 400 configured for executing a method as described herein. System 400 comprises at least one reaction chamber which is configured for performing a pretreatment step and depositing the silicon nitride on the treated surface as described herein. System 400 may comprise a first reaction chamber 411 and a second reaction chamber 412 that may both be configured for pretreating and depositing silicon nitride as described herein. If desired, system 400 can include a third reaction chamber 413 in which another process, such as a thermal or plasma-enhanced post treatment may be carried out.

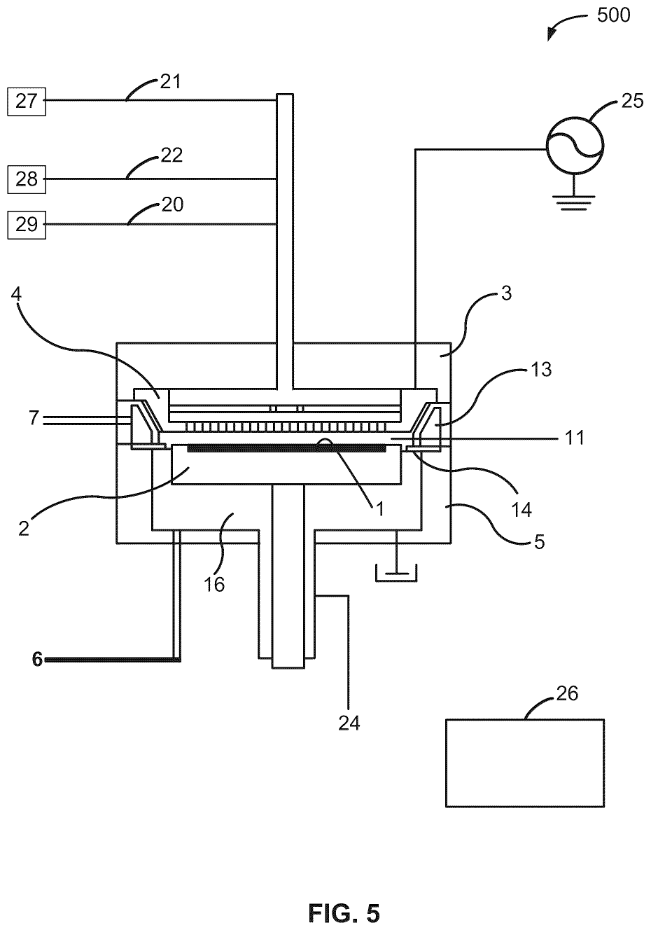

FIG. 5 illustrates an exemplary reaction system (e.g., suitable for use as reaction chamber 411 or 412) in greater detail. Reactor system 500 can be used to perform one or more steps or sub steps as described herein and/or to form one or more structures or portions thereof as described herein.

Reactor system 500 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 13.56 MHz or 27 MHz or 60 MHz) from power source 25 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature. Electrode 4 can serve as a gas distribution device, such as a shower plate. Reactant gas, dilution gas, if any, precursor gas, and/or the like can be introduced into reaction chamber 3 using one or more of a gas line 20, a gas line 21, and a gas line 22, respectively, and through the shower plate 4. Although illustrated with three gas lines, reactor system 500 can include any suitable number of gas lines. Gas line 20 can be coupled to a silicon precursor source 29, gas line 21 can be coupled to an inert gas source 27, and gas line 22 can be coupled to a reactant gas source 28.

In reaction chamber 3, an annular duct 13 with an exhaust line 7 is provided, through which gas in the interior 11 of the reaction chamber 3 can be exhausted. Additionally, a transfer region 5, disposed below the reaction chamber 3, is provided with a seal gas line 24 to introduce seal gas into the interior 11 of the reaction chamber 3 via the interior 16 (transfer zone) of the transfer region 5, wherein a separation plate 14 for separating the reaction zone and the transfer zone is provided (a gate valve through which a wafer is transferred into or from the transfer region 5 is omitted from this figure). The transfer region is also provided with an exhaust line 6. In some embodiments, the deposition and treatment steps are performed in the same reaction space, so that two or more (e.g., all) of the steps can continuously be conducted without exposing the substrate to air or other oxygen-containing atmosphere.

In some embodiments, continuous flow of an inert or carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching between the main line and the detour line, without substantially fluctuating pressure of the reaction chamber.

Reactor system 500 also includes one or more controller(s) 26 programmed or otherwise configured to cause one or more method steps as described herein to be conducted. Controller(s) 26 are communicated with the various power sources, heating systems, pumps, robotics and gas flow controllers, or valves of the reactor, as will be appreciated by the skilled artisan. By way of examples, controller 26 can be configured to control gas flow of a silicon precursor and a reactant during deposition and pretreatment steps. Additionally or alternatively, the controller can be configured to control pressure and/or temperature within the reaction chamber and/or to control power applied to at least one of the electrodes.

In some embodiments, a dual chamber reactor (two sections or compartments for processing wafers disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

What is claimed is:

1. A method of forming silicon nitride on a surface of a substrate, the method comprising the steps of:
providing a substrate within a reaction chamber;
performing a pretreatment step on a surface of the substrate and within the reaction chamber, the pretreatment step comprising:
providing one or more gases comprising nitrogen and hydrogen to the reaction chamber; and
forming activated species from the one or more gases comprising nitrogen and hydrogen and using the activated species to form a treated surface; and
depositing the silicon nitride on the treated surface,
wherein a pressure within the reaction chamber during the step of performing the pretreatment step is greater than or equal to 3000 Pa.

2. The method according to claim 1, wherein the step of depositing the silicon nitride comprises a cyclical deposition process comprising:
pulsing a silicon precursor to the reaction chamber for a silicon precursor pulse period;
providing the one or more gases comprising nitrogen and hydrogen; and
pulsing a plasma power for a plasma power pulse period.

3. The method according to claim 2, further comprising repeating the cyclical deposition process a number (n) times, wherein n is greater than 1.

4. The method according to claim 1, wherein a pressure within the reaction chamber during the step of performing a pretreatment is greater than a pressure within the reaction chamber during the step of depositing the silicon nitride.

5. The method according to claim 1, wherein a pressure within the reaction chamber during the step of performing a pretreatment is more than 150% of a pressure within the reaction chamber during the step of depositing the silicon nitride.

6. The method according to claim 1, wherein the one or more gases comprising nitrogen and hydrogen is provided continuously during performing the pretreatment step and the step of depositing the silicon nitride.

7. The method according to claim 1, wherein the surface of the substrate comprises one or more of silicon, silicon oxide, a metal, or a metal oxide, with or without fluorine terminal bonds.

8. The method according to claim 1, wherein the silicon precursor is selected from the group consisting of a silane, a silylamine, an aminosilane, and a halogenated silicon compound.

9. The method according to claim 8, wherein the silicon precursor is selected from one or more of silane (SiH₄), disilane (Si₂H₆), trisilane (Si₃Hg), tetrasilane (Si₄H₁₀), N(Si₂H₅)₃, trisilylamine N(SiH₃)₃, N(SiMe₃)(SiHMeNMe₂)2, 2,2-disilyltrisilane (Si(SiH₃)₄), trisdimethylaminosilane (SiH(NMe₂)₃), bis(diethylamino)silane (SiH₂(NEt₂)₂) (BEDAS), bis(tert-butylamino)silane (SiH₂(NHtBu)₂) (BTBAS), di-isopropylamido)silane (SiH₃(NiPr₂)) (DIPAS), where Me represents a methyl group, Et represents an ethyl group, tBu represents a tert-butyl group, and iPr represents an isopropyl group, trichloro disilane (Si₂Cl₃H₃), pentachloro disilane (Si₂Cl₅H), hexachloro disilane (Si₂Cl₆), octachlorotrisilane (Si₃Cl₈), dichloro silane (SiCl₂H₂), dimethyldichlorosilane (SiCl₂Me₂), tetrachloro silane (SiCl₄), tetraiodo silane (SiI₄), triiodo silane (SiI₃H), and diiodo silane (SiI₂H₂).

10. The method according to claim 1, wherein the one or more gases comprising nitrogen and hydrogen comprise a mixture of nitrogen and hydrogen and one or more of argon and helium.

11. The method according to claim 10, wherein the mixture of nitrogen and hydrogen comprises from about 70 to about 100 volumetric percent nitrogen and/or from about 0 to about 1 volumetric percent hydrogen.

12. The method according to claim 1, wherein the one or more gases comprising nitrogen and hydrogen comprise one or more of ammonia, hydrazine, and a hydrazine derivative.

13. The method according to claim 12, wherein the one or more gases comprising nitrogen and hydrogen comprise a second gas comprising one or more of argon, helium, and nitrogen.

14. The method according to claim 1, wherein a power used to form a plasma during the step of forming activated species from the one or more gases comprising nitrogen and hydrogen is between about 10 W and about 2 kW.

15. The method according to claim 1, wherein a pressure within the reaction chamber during performing a pretreatment step is between greater than 3000 Pa and 4000 Pa.

16. The method according to claim 1, wherein a temperature within the reaction chamber during performing a pretreatment step is between about 100° C. and about 600° C. or about 300° C. and about 550° C.

17. The method according to claim 1, wherein a duration of the performing a pretreatment step is between about 1 and about 300 seconds or between about 30 and about 240 seconds.

18. The method according to claim 2, wherein the silicon precursor pulse period ceases prior to the step of pulsing a plasma power for a plasma power pulse period.

19. The method according to claim 1, wherein a pressure within the reaction chamber during the step of depositing the silicon nitride is between 350 Pa and less than 3000 Pa.

20. A system for performing the steps of claim 1.
